(19) United States
(12) Patent Application Publication
(10) Pub. No.: US 2026/0036649 A1
(43) Pub. Date: Feb. 5, 2026

(54) SUBSEA HIGH VOLTAGE LOOP CAP FOR TESTING AND MONITORING SUBSEA ELECTRICAL POWER SYSTEMS

(71) Applicant: Chevron U.S.A. Inc., San Ramon, CA (US)

(72) Inventors: Murtaza Hussain, Oslo (NO); Masoud Hajiaghajani, Houston, TX (US)

(21) Appl. No.: 18/791,588

(22) Filed: Aug. 1, 2024

(51) Int. Cl. G01R 31/58

(52) U.S. Cl. CPC G01R 31/58

(57) ABSTRACT

An loop cap can include a base having an outer surface and an inner surface, wherein the outer surface is configured to be exposed to a subsea environment. The loop cap can also include a first terminal that extends through the base, where the first terminal has a first proximal portion that is configured to be electrically coupled to a first electrical conductor providing high voltage power to a subsea electrical system. The loop cap can further include a second terminal that extends through the base, where the second terminal has a second proximal portion that is configured to be electrically coupled to a second electrical conductor providing high voltage power to the subsea electrical system. The loop cap can also include a jumper that provides electrical continuity between the first terminal and the second terminal.

### TECHNICAL FIELD

The present application is related to subsea electrical power systems and, more particularly, to subsea high voltage loop caps for testing and monitoring subsea electrical systems.

### BACKGROUND

Subsea electrical systems, particularly those subsea electrical systems operating at higher voltages ≥1 kV, are subject to various electrical faults (e.g., phase-to-ground faults, phase-to-phase faults) that can cause an outage, which necessarily causes a halt to the associated operations (e.g., oil and gas field operations, water operations, hydrogen operations, offshore wind generation, subterranean injection and/or storage operations). In the current art, a fully isolated dummy cap (FIDC) is used to facilitate testing of subsea electrical systems. Specifically, a FIDC serves as a test port that a measuring device (e.g., a meter) can be plugged into to detect certain conditions associated with the subsea electrical system. However, a FIDC is only configured to allow such a measuring device to perform certain types of tests (e.g., insulation resistance tests, time domain reflectometry (TDR) tests, very low frequency (VLF) tests, other testing methods not requiring a loop cap) to reveal certain types of fault conditions associated with the subsea electrical system.

In addition, the tests that can be performed using existing FIDCs use direct current and since the cap is not looped, the data that can be obtained is limited. For example, with a subsea transformer that is galvanically isolated, using a FIDC at the secondary winding while testing the primary windings and upstream of the subsea transformer prevents a user from obtaining data that can indicate the condition of the secondary windings and downstream of the subsea transformer. Also, the existing FIDCs are unable to facilitate the performance of other types of tests (e.g., continuity line resistance testing (AC or DC), bridge method testing, AC loop impedance metering, vector impedance metering, line resonance analysis (LIRA), Impulse Current Method (ICM)). As a result, FIDCs provide limited fault finding, condition monitoring, and fingerprinting data during site acceptance tests, commissioning, and operations to identify and locate a fault or to assess system integrity.

### SUMMARY

In general, in one aspect, the disclosure relates to a loop cap can include a base having an outer surface and an inner surface, where the outer surface is configured to be exposed to a subsea environment. The loop cap can also include a first terminal that extends through the base, where the first terminal has a first proximal portion that is configured to be electrically coupled to a first electrical conductor providing high voltage power to a subsea electrical system. The loop cap can further include a second terminal that extends through the base, where the second terminal has a second proximal portion that is configured to be electrically coupled to a second electrical conductor providing high voltage power to the subsea electrical system. The loop cap can also include a jumper that provides electrical continuity between the first terminal and the second terminal.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positions may be exaggerated to help visually convey such principles. In the drawings, the same reference numerals used in different figures may designate like or corresponding but not necessarily identical elements.

FIG. 1 shows a block diagram of a general subsea electrical system according to certain example embodiments.

FIG. 2 shows an embodiment of a subsea electrical system according to certain example embodiments.

FIG. 3 shows another embodiment of a subsea electrical system according to certain example embodiments.

FIG. 4 shows a schematic diagram of a subsea electrical system according to certain example embodiments.

FIG. 5 shows a schematic diagram of another subsea electrical system according to certain example embodiments.

FIG. 6 shows a general component diagram of an example loop cap according to certain example embodiments.

FIGS. 7A and 7B show a top view and a front view, respectively, of a loop cap according to certain example embodiments.

FIGS. 8A through 8C show various configurations of a jumper for a loop cap according to certain example embodiments.

FIG. 9 shows a computing device in accordance with certain example embodiments.

### DETAILED DESCRIPTION

The example embodiments discussed herein are directed to systems, apparatus, methods, and devices for loop caps. Example embodiments may be used for measuring one or more parameters associated with some or all of a subsea electrical system. Example embodiments may be used in any depth (e.g., 100 m, 1000 m, 5000 m, 10000 m) of water in which a subsea electrical system (or equipment thereof) is located and/or any distance above the seabed floor that a subsea electrical system (or equipment thereof) is located. Example embodiments described herein may be directed toward data collection with respect to any type of subsea electrical equipment, including but not limited to transformers, converters, inverters, motors, compressors, and cables. Example embodiments may be used with subsea electrical equipment that operate using a voltage of at least 1 kV voltages (e.g., 12 kV, 36 kV, 245 kV).

Example loop caps can be made of one or more of a number of suitable materials to allow the loop caps to meet certain standards and/or regulations while also maintaining durability in light of the one or more conditions under which the loop caps may be exposed. Examples of such materials can include, but are not limited to, titanium, aluminum, stainless steel, galvanized steel, ceramics, plastic (e.g., polytetrafluoroethylene (PTFE), nylon), and a polymer (e.g., an acetal homopolymer, a copolymer of terephthalic acid (1,4) and ethylene glycol). An example loop cap can either be (1) fully insulated and rated to at least the Um value of its corresponding connector system, or (2) have a reduced insulation level to allow for simplified testing (e.g., continuity testing, insulation resistance testing).

Example loop caps, or portions or components thereof, described herein can be made from a single piece (e.g., from a mold, using injection molding, using a die cast process, using a milling and/or lathing process, using an extrusion process, 3D printing). In addition, or in the alternative, example loop caps (including portions or components thereof) can be made from multiple pieces that are mechanically coupled to each other. In such a case, the multiple pieces can be mechanically coupled to each other using one or more of a number of coupling methods, including but not limited to epoxy, welding, fastening devices, compression fittings, mating threads, snap fittings, and slotted fittings. One or more pieces that are mechanically coupled to each other can be coupled to each other in one or more of a number of ways, including but not limited to fixedly, hingedly, removeably, slidably, rotatably, and threadably.

The use of the terms “about”, “approximately”, and similar terms applies to all numeric values, whether or not explicitly indicated. These terms generally refer to a range of numbers that one of ordinary skill in the art would consider as a reasonable amount of deviation to the recited numeric values (i.e., having the equivalent function or result). For example, this term may be construed as including a deviation of +10 percent of the given numeric value provided such a deviation does not alter the end function or result of the value. Therefore, a value of about 1% may be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

A “subterranean formation” refers to practically any volume under a surface. For example, it may be practically any volume under a terrestrial surface (e.g., a land surface), practically any volume under a seafloor, etc. Each subsurface volume of interest may have a variety of characteristics, such as petrophysical rock properties, reservoir fluid properties, reservoir conditions, hydrocarbon properties, or any combination thereof. For example, each subsurface volume of interest may be associated with one or more of: temperature, porosity, salinity, permeability, water composition, mineralogy, hydrocarbon type, hydrocarbon quantity, reservoir location, pressure, etc. Those of ordinary skill in the art will appreciate that the characteristics are many, including, but not limited to, shale gas, shale oil, tight gas, tight oil, tight carbonate, carbonate, vuggy carbonate, unconventional (e.g., a permeability of less than 25 millidarcy (mD) such as a permeability of from 0.000001 mD to 25 mD)), diatomite, geothermal, mineral, etc. The terms “formation”, “subsurface formation”, “hydrocarbon-bearing formation”, “reservoir”, “subsurface reservoir”, “subsurface area of interest”, “subsurface region of interest”, “subsurface volume of interest”, and the like may be used synonymously. The term “subterranean formation” is not limited to any description or configuration described herein.

A “well” or a “wellbore” refers to a single hole, usually cylindrical, that is drilled into a subsurface volume of interest. A well or a wellbore may be drilled in one or more directions. For example, a well or a wellbore may include a vertical well, a horizontal well, a deviated well, and/or other type of well. A well or a wellbore may be drilled in the subterranean formation for exploration and/or recovery of resources. A plurality of wells (e.g., tens to hundreds of wells) or a plurality of wellbores are often used in a field depending on the desired outcome.

A well or a wellbore may be drilled into a subsurface volume of interest using practically any drilling technique and equipment known in the art, such as geosteering, directional drilling, etc. Drilling the well may include using a tool, such as a drilling tool that includes a drill bit and a drill string. Drilling fluid, such as drilling mud, may be used while drilling in order to cool the drill tool and remove cuttings. Other tools may also be used while drilling or after drilling, such as measurement-while-drilling (MWD) tools, seismic-while-drilling tools, wireline tools, logging-while-drilling (LWD) tools, or other downhole tools. After drilling to a predetermined depth, the drill string and the drill bit may be removed, and then the casing, the tubing, and/or other equipment may be installed according to the design of the well. The equipment to be used in drilling the well may be dependent on the design of the well, the subterranean formation, the hydrocarbons, and/or other factors.

A well may include a plurality of components, such as, but not limited to, a casing, a liner, a tubing string, a sensor, a packer, a screen, a gravel pack, artificial lift equipment (e.g., an electric submersible pump (ESP)), and/or other components. If a well is drilled offshore, the well may include one or more of the previous components plus other offshore components, such as a riser. A well may also include equipment to control fluid flow into the well, control fluid flow out of the well, or any combination thereof. For example, a well may include a wellhead, a choke, a valve, and/or other control devices. These control devices may be located on the surface, in the subsurface (e.g., downhole in the well), or any combination thereof. In some embodiments, the same control devices may be used to control fluid flow into and out of the well. In some embodiments, different control devices may be used to control fluid flow into and out of a well.

In some embodiments, the rate of flow of fluids through the well may depend on the fluid handling capacities of the surface facility that is in fluidic communication with the well. The equipment to be used in controlling fluid flow into and out of a well may be dependent on the well, the subsurface region, the surface facility, and/or other factors. Moreover, sand control equipment and/or sand monitoring equipment may also be installed (e.g., downhole and/or on the surface). A well may also include any completion hardware that is not discussed separately. The term “well” may be used synonymously with the terms “borehole,” “wellbore,” or “well bore.” The term “well” is not limited to any description or configuration described herein.

It is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components.

For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C.

In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C).

In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

If a component of a figure is described but not expressly shown or labeled in that figure, the label used for a corresponding component in another figure may be inferred to that component. Conversely, if a component in a figure is labeled but not described, the description for such component may be substantially the same as the description for the corresponding component in another figure. The numbering scheme for the various components in the figures herein is such that each component is a three-digit number, and corresponding components in other figures have the identical last two digits. For any figure shown and described herein, one or more of the components may be omitted, added, repeated, and/or substituted. Accordingly, embodiments shown in a particular figure should not be considered limited to the specific arrangements of components shown in such figure.

Further, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein.

Example embodiments of loop caps will be described more fully hereinafter with reference to the accompanying drawings, in which example embodiments of loop caps are shown. Loop caps may, however, be embodied in many different forms and should not be construed as limited to the example embodiments set forth herein. Rather, these example embodiments are provided so that this disclosure will be thorough and complete, and will fully convey the scope of loop caps to those of ordinary skill in the art. Like, but not necessarily the same, elements (also sometimes called components) in the various figures are denoted by like reference numerals for consistency.

Terms such as “first”, “second”, “primary,” “secondary,” “above”, “below”, “inner”, “outer”, “distal”, “proximal”, “end”, “top”, “bottom”, “upper”, “lower”, “side”, “left”, “right”, “front”, “rear”, and “within”, when present, are used merely to distinguish one component (or part of a component or state of a component) from another. This list of terms is not exclusive. Such terms are not meant to denote a preference or a particular orientation, and they are not meant to limit embodiments of loop caps. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

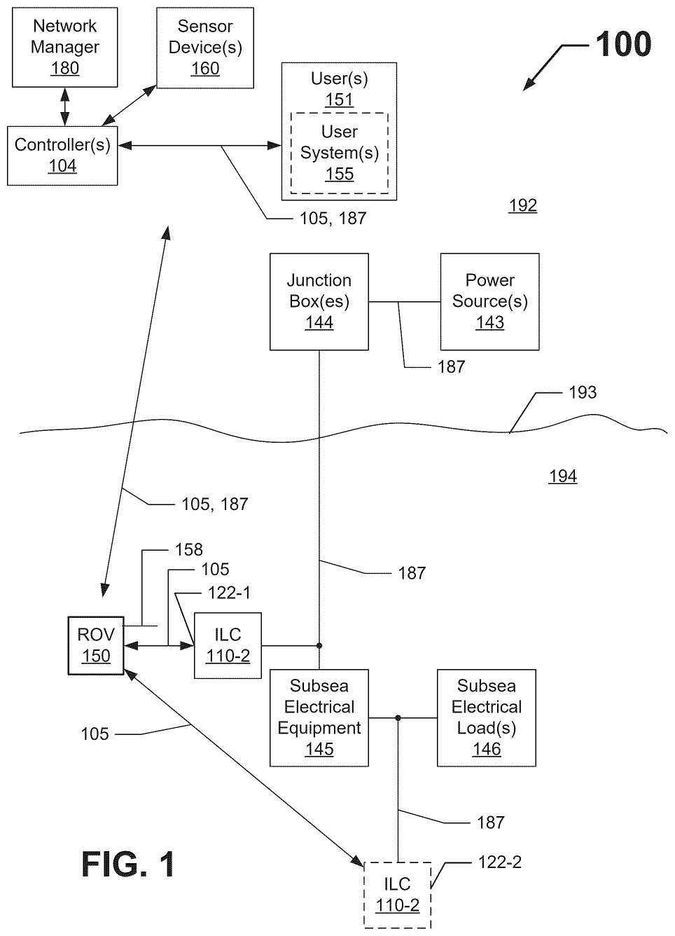

FIG. 1 shows a block diagram of a general subsea electrical system 100 according to certain example embodiments. The subsea electrical system 100 in this case includes some components located in water 194 (subsea) and other components located in air 192 above the waterline 193 (outside of the water 194). In this case, a remotely operated vehicle (ROV) 150, one or more example insulated loop caps (ILCs) 110, subsea electrical equipment 145, and one or more subsea electrical loads 146 are located in the water 194. Also in this case, one or more junction boxes 144, one or more power sources 143, a network manger 180, one or more controllers 104, one or more sensor devices 160, and one or more users 151, each of which may include one or more user systems 155.

The components shown in FIG. 1 are not exhaustive, and in some embodiments, one or more of the components shown in FIG. 1 may not be included in the example subsea electrical system 100. Any component of the subsea electrical system 100 may be discrete or combined with one or more other components of the subsea electrical system 100. Also, one or more components of the subsea electrical system 100 may have different configurations. For example, one or more of the sensor devices 160 may be submerged in the water 194 rather than being positioned in the air 192. As another example, a controller 104, rather than being a stand-alone device, may be part of one or more other components (e.g., the ROV 150) of the subsea electrical system 100.

In some cases, the ROV 150, one or more of the example ILCs 110, one or more of the users 151 (including the associated user systems 155), one or more of the controllers 104, one or more of the sensor devices 160, and/or the network manager 180 may transmit communication signals and/or power signals using one or more communication links 105 and/or one or more power transfer links 187, both of which are described below.

A user 151 may be any person that interacts, directly or indirectly, with the subsea electrical system 100, including one or more of the example ILCs 110, the subsea electrical equipment 145, the subsea electrical load 146, and/or any other component of the subsea electrical system 100. Examples of a user 151 may include, but are not limited to, a business owner, an engineer, a company representative, an operator, a technician, an electrician, a consultant, a contractor, and a manufacturer's representative. A user 151 may use one or more user systems 155, which may include a display (e.g., a GUI). A user system 155 of a user 151 may interact with (e.g., send data to, obtain data from) the example ILCs 110, a controller 104, the network manager 180, the sensor devices 160, and/or any other component of the subsea electrical system 100 via an application interface and using the communication links 105 (discussed below). The user 151 (including an associated user system 155) may also interact directly with the example ILCs 110, one or more of the controllers 104, the network manager 180, one or more of the sensor devices 160, and/or any other component of the subsea electrical system 100 through a user interface (e.g., a probe, an electrical connector, keyboard, mouse, touchscreen).

A user system 155 of a user 151 interacts with (e.g., sends data to, receives data from) an example ILC 110 via an application interface. Examples of a user system 155 may include, but are not limited to, a cell phone with an app, a laptop computer, a handheld device, a smart watch, a desktop computer, and an electronic tablet. In some cases, a user 151 (including an associated user system 155) may also interact directly with the network manager 180, one or more of the controllers 104, one or more of the example ILCs 110, the ROV 150, one or more of the sensor devices 160, and/or any other components in the subsea electrical system 100 using one or more communication links 105.

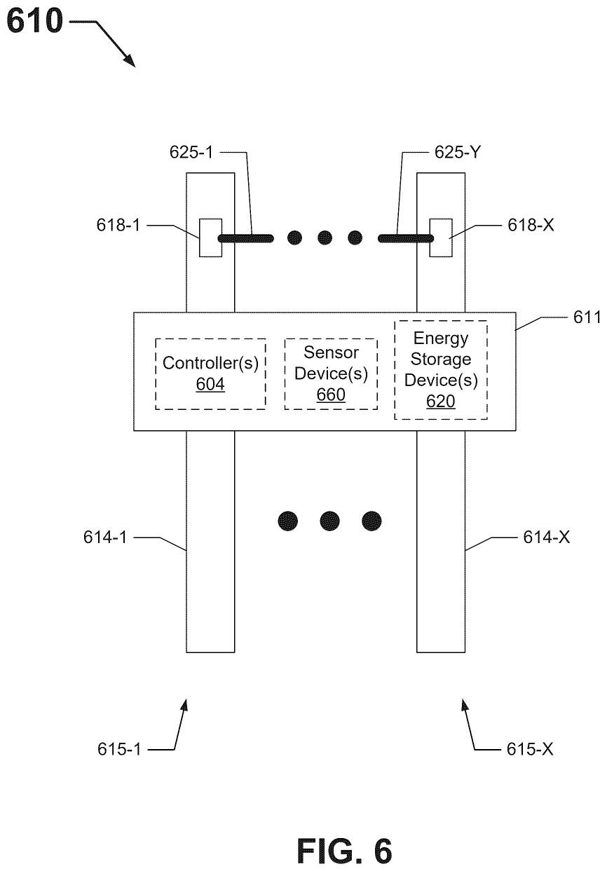

The network manager 180 is a device or component that controls all or a portion (e.g., a communication network, a controller 104, an example ILC 110) of the subsea electrical system 100. The network manager 180 may be substantially similar to the controller of an example ILC 110, discussed below. For example, the network manager 180 may include a controller that has one or more components and/or similar functionality to some or all of the controller of an ILC 110. Alternatively, the network manager 180 may include one or more of a number of features in addition to, or altered from, the features of the controller of an ILC 110. As described herein, control and/or communication with the network manager 180 may include communicating with one or more other components of the same subsea electrical system 100 or another system. In such a case, the network manager 180 may facilitate such control and/or communication. The network manager 180 may be called by other names, including but not limited to a master controller, a network controller, and an enterprise manager. The network manager 180 may be considered a type of computer device, as discussed below with respect to FIG. 6.

As mentioned above, the subsea electrical system 100 may include one or more controllers 104. Each controller 104 may be communicably coupled to the network manager 180. A controller 104 may also be communicably coupled to one or more other components of the subsea electrical system 100, including but not limited to the one or more example ILCs 110, one or more of the users 151 (including associated user systems 155), the network manager 180, some or all of the subsea electrical equipment 145, the ROV 150, and one or more of the sensor devices 160. A controller 104 may perform a number of functions that may include obtaining and sending data, evaluating data, following protocols, running algorithms, and sending commands.

A controller 104 of FIG. 1 may include one or more of a number of components. For example, components of a controller 104 may include, but are not limited to, a control engine, a communication module, a timer, a counter, a power module, a storage repository, a hardware processor, memory, a transceiver, an application interface, and a security module.

When there are multiple controllers 104 (e.g., one controller 104 for switches in the subsea electrical equipment 145, another controller 104 for a system on the topsides of a floating structure, yet another controller for the ROV 150), each controller 104 may operate independently of each other. Alternatively, one or more of the controllers 104 may work cooperatively with each other. As yet another alternative, one of the controllers 104 may control some or all of one or more other controllers 104 in the subsea electrical system 100. As still another alternative, one or more of the controllers 104 may be in communication with and controlled by the controller of an example ILC 110. Each controller 104 may be considered a type of computer device, as discussed below with respect to FIG. 6.

Each sensor device 160 includes one or more sensors that measure one or more parameters (e.g., pressure, flow rate, temperature, humidity, fluid content, voltage, current, voltage differential, current differential, resistance, electrical continuity, presence of an object or component, chemical elements in a fluid, vibrations, movement, subsea current, metocean data). Examples of a sensor of a sensor device 160 may include, but are not limited to, a temperature sensor, a flow sensor, a pressure sensor, a proximity sensor, a gas spectrometer, a vibration sensor, an accelerometer, a gyroscope, an infrared transceiver, a voltmeter, an ammeter, a permeability meter, a porosimeter, and a camera. A sensor device 160 may be integrated with or measure a parameter associated with one or more components of the subsea electrical system 100. For example, a sensor device 160 may be configured to measure a parameter (e.g., current, voltage, real power, VARs) associated with the operation and/or condition of the subsea electrical equipment 145 and/or the subsea electrical load 146.

In some cases, a number of sensor devices 160, each measuring a different parameter, may be used in combination to determine and confirm whether a controller 104 should take a particular action (e.g., operate a valve, operate or adjust the operation of a pump, send a notification). When a sensor device 160 includes its own controller (e.g., a controller 104), or portions thereof, then the sensor device 160 may be considered a type of computer device, as discussed below with respect to FIG. 6.

The remotely operated vehicle (ROV) 150 may be configured to be dispatched into the water 194 on occasion to perform an inspection of one or more components (e.g., the subsea electrical equipment 145, the subsea electrical load 146, mooring lines, the hull) of the subsea electrical system 100, a related system (e.g., a floating platform), and/or one or more aspects (e.g., the seabed) associated with the subsea electrical system 100. In certain example embodiments, the ROV 150 is additionally or alternatively configured to communicate with one or more of the example ILCs 110 using one or more communication links 105 (e.g., wirelessly using Bluetooth, using a probe, using an electrical connector end).

The ROV 150 may be autonomous (e.g., operates based on instructions or an objective) or controlled remotely, via communication links 105, by a user 151 (e.g., on the topsides of a floating structure) using a control device in the form of a user system 155. In some cases, the ROV 150 may include an energy storage device (e.g., a battery) and/or some other source of power that is in addition to or an alternative of the power that may flow through the power transfer links 187 (e.g., via a cable). The ROV 150 may include one or more of its own controllers (e.g., similar to a controller 104) and/or one or more of its own sensor devices (e.g., similar to a sensor device 160). The ROV 150 may be configured to communicate with (e.g., send instructions to, receive data from) one or more of the example ILCs 110 using an extension 158, which is configured to become coupled to (e.g., inserted into) a coupling feature 122 of the ILC 110.

The ROV 150 may also include other equipment (e.g., a motor, a propeller, a battery) to help the ROV 150 move in a controlled manner within the water 194. In some cases, the ROV 150 may be tethered (e.g., physically with a cable, wirelessly) to a base station that is located at or near the topsides of a floating structure in the water 194. Each controller 104 of a ROV 150 may be a type of computer device discussed below with respect to FIG. 6. If a sensor device 160 of a ROV 150 includes functionality of some or all of a controller, then the sensor device 160 may be a type of computer device discussed below with respect to FIG. 6.

The subsea electrical system 100 may include any number (e.g., one, two, five, 10, 35) of ILCs 110. In this case, the subsea electrical system 100 includes two ILCs 110 (ILC 110-1 having coupling feature 122-1 and ILC 110-2 having coupling feature 122-2). Each ILC 110 is configured to facilitate, on a discrete or continuous basis, testing and/or monitoring of some or all of the subsea electrical equipment 145 and/or the subsea electrical load 146. Each ILC 110 is electrically coupled in parallel with one or more conductors of one or more electrical cables that serve as power transfer links 187 providing power to the subsea electrical equipment 145 from a junction box 144 and/or from the subsea electrical equipment 145 to the subsea electrical load 146. In this case, ILC 110-1 is connected in parallel to the power transfer link 187 on the high side (between the subsea electrical equipment 145 and the junction box 144) of and proximate to the subsea electrical equipment 145. Also, ILC 110-2 is connected in parallel to the power transfer link 187 on the low side (between the subsea electrical equipment 145 and the subsea electrical load 146) of and proximate to the subsea electrical equipment 145.

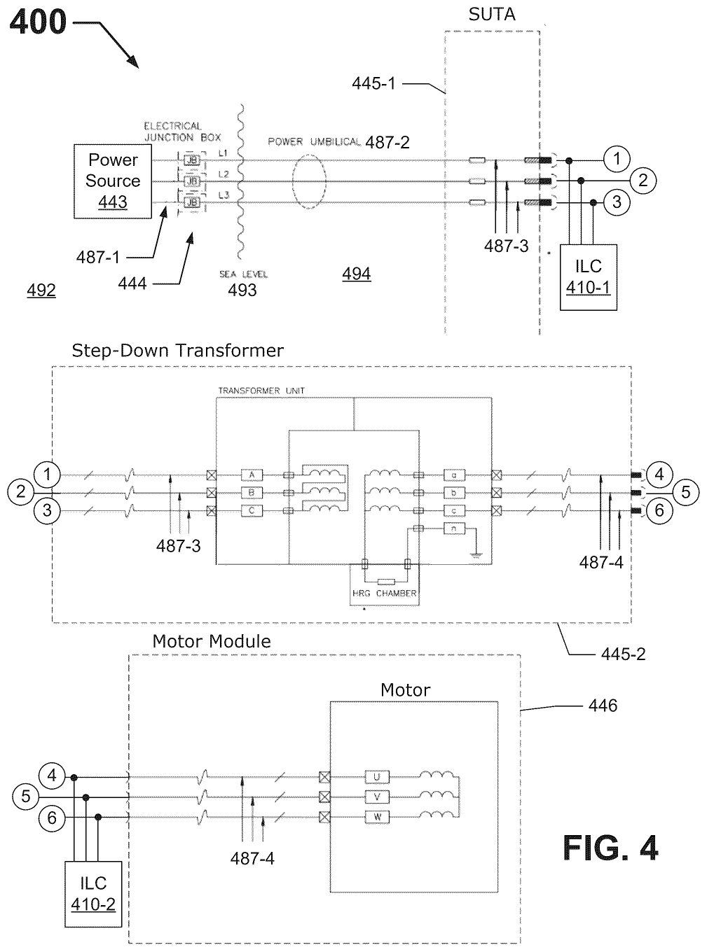

In some cases, an ILC 110 is a purely mechanical device, providing an electrical connector end that complements an electrical connector end on the ROV 150. In addition, or in the alternative, a ILC 110 may include electronics (e.g., a controller (e.g., similar to a controller 104), a sensor device (e.g., similar to a sensor device 160)) that allow the ILC 110 to measure power-related parameters, perform subsea testing, store the measurements, follow protocols, run models or other forms of algorithms using the measurements, communicate with the ROV 150 and/or a user system 155 using communication links 105 (e.g., wirelessly, by coupling complementary connector ends), assess results of the models, and/or perform other functions. More details about an example ILC 110 are provided below with respect to FIG. 4.

Each power source 143 of the subsea electrical system 100 is or includes one or more sources of electrical power that can provide power over relatively long distances (e.g., hundreds of m, thousands of m, dozens of km) and at relatively high voltages (e.g., 1 kV or greater) for the subsea electrical load 146. Examples of a power source 143 may include, but are not limited to, a diesel-powered generator, a natural gas generator, a photovoltaic solar system, and an energy storage device (e.g., a battery, a supercapacitor).

Each junction box 144 of the subsea electrical system 100 is configured to connect terminations of one or more electrical cables (e.g., a form of power transfer link 187) from the power sources 143 with terminations of one or more electrical cables from the subsea electrical equipment 145. Each junction box 144 may include an enclosure that may be opened to expose the electrical connections. In such a case, the enclosure may be configured (e.g., in terms of material, in terms of sealing devices, in terms of flame paths) in such a way that the enclosure complies with applicable standards for the environment (e.g., hazardous, marine, explosive) in which the junction box 144 is placed. A junction box 144 may have or includes any of a number of other components (e.g., breakers, switches, protective relays, a sensor device (e.g., sensor device 160), a controller (e.g., controller 104)). In some cases, a junction box 144 as defined herein may be transition splices in one or more electrical cables that exist outside of any enclosure. In other words, a junction box 144 as defined herein is directed to a location where multiple electrical cables are spliced together or share a common electrical termination point, with or without a physical box or other type of enclosure.

The subsea electrical equipment 145 of the subsea electrical system 100 is configured to manipulate (e.g., transform, convert, invert) power received from one or more of the junction boxes 144 into a level (e.g., 400 V, 7.2 kV) and type (e.g., alternating current, direct current) of power that may be used by the subsea electrical equipment 145. The subsea electrical equipment 145 may include one or more of a number of different components. Examples of such components may include, but are not limited to, a transformer, an inverter, a converter, an inductor, a capacitor, a circuit breaker, a switch, a protective relay, a sensor device (e.g., sensor device 160), and a controller (e.g., controller 104). The subsea electrical equipment 145 may be configured to operate in water 194 (e.g., salt water, fresh water) at potentially large depths (e.g., hundreds of feet, thousands of feet) at or near a seabed.

The subsea electrical load 146 of the subsea electrical system 100 is configured to perform one or more subsea functions by virtue of its operation. The subsea electrical load 146 operates using high voltage (e.g., at least 1 kV) power provided by the subsea electrical equipment 145 via one or more electrical cables (e.g., a form of power transfer link 187). The subsea electrical load 146 can be or include one or more of a number of components. Examples of such components may include, but are not limited to, a pump, a motor, a compressor, a distribution system, a sensor device (e.g., sensor device 160), and a controller (e.g., controller 104). The subsea electrical equipment 145 may be configured to operate in water 194 (e.g., salt water, fresh water) at potentially large depths (e.g., hundreds of feet, thousands of feet) at or near a seabed.

Communication between the network manager 180, the users 151 (including any associated user systems 155), the controllers 104, the sensor devices 160, the example ILCs 110, the ROV 150, and any other components of the subsea electrical system 100 may be facilitated using the communication links 105. Each communication link 105 may include wired (e.g., Class 1 electrical cables, electrical connectors, Power Line Carrier) and/or wireless (e.g., sound or pressure waves in the water 194, Wi-Fi, Zigbee, visible light communication, cellular networking, Bluetooth, Bluetooth Low Energy (BLE), ultrawide band (UWB), Wireless HART, ISA100) technology.

Similarly, the transfer of power between any two components (e.g., the subsea electrical equipment 145 and the subsea electrical load 146, a power source 143 and a junction box 144) of the subsea electrical system 100 may be facilitated using power transfer links 187. Each power transfer link 187 may include one or more electrical conductors, which may be individual or part of one or more electrical cables. In some cases, as with inductive power, power may be transferred wirelessly using power transfer links 187. A power transfer link 187 may transmit power from one component of the subsea electrical system 100 to another. Each power transfer link 187 may be sized (e.g., 12 gauge, 18 gauge, 4 gauge) in a manner suitable for the amount (e.g., 480V, 4 kV, 120V, 115 kV) and type (e.g., alternating current, direct current) of power transferred therethrough.

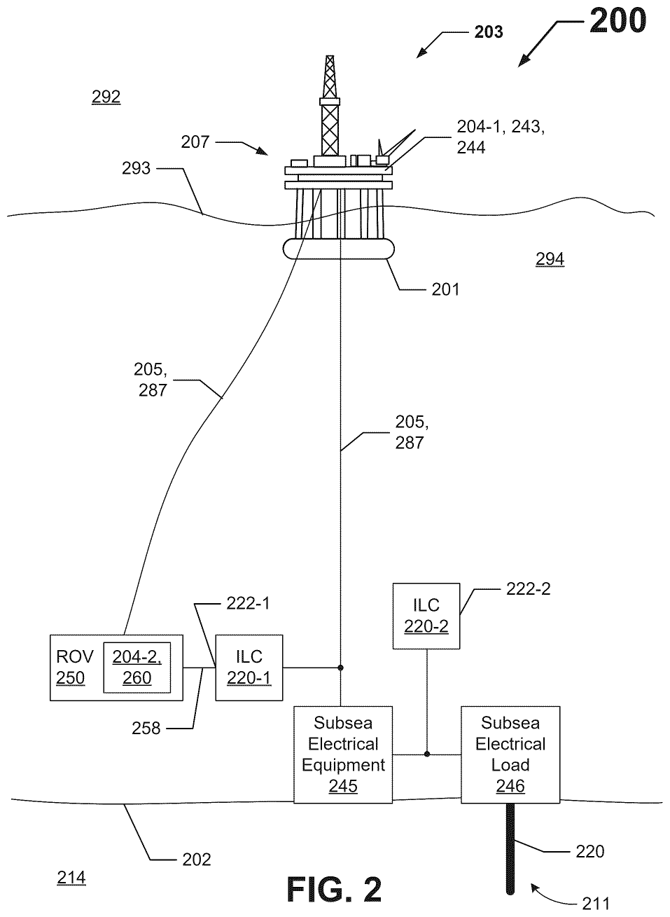

FIG. 2 shows an embodiment of a subsea electrical system 200 (also sometimes more simply called a system 200) according to certain example embodiments. Referring to the description above with respect to FIG. 1, the system 200 of FIG. 2 in this case includes a floating structure 203 in the form of a semi-submersible platform that floats in a large and deep body of water 294. Part (e.g., the topsides 207) of the floating structure 203 is exposed to air 292 above the water line 293, and at least part (e.g., part of the hull 201) of the rest of the floating structure 203 is in the water 294 (subsea) below the water line 293.

The floating structure 203 in this case is used for subterranean field operations (also called subsea field operations herein), in which exploration and production phases (also called stages) of the subsea field operation are executed to extract one or more subterranean resources 211 (e.g., oil, natural gas, water, hydrogen gas) from and/or inject resources (e.g., carbon monoxide) into the subterranean formation 214 via a wellbore 220. Located on the topsides 207 of the floating structure 203 in this case are a power source 243 (substantially similar to the power sources 143 discussed above), a controller 204-1 (substantially similar to the controllers 104 discussed above), and a junction box 244 (substantially similar to the junction boxes 244 discussed above). There may be one or more of a number of other components (e.g., a sensor device) disposed on the topsides 207 of the floating structure 203.

In alternative embodiments, as when a subsea operation is in water 294 with relatively shallow depths, the structure 203 can be mounted on the seabed 202 with the topsides 207 raised above the water line 293. Further, in some cases, a field operation involves multiple wellbores 220 that originate from the same proximate location (sometimes called a pad) on the seabed 202. In such cases, the wellbores 220 can be drilled one at a time, and the wells from a pad can be on production simultaneously.

The subsea electrical load 246 (substantially similar to the subsea electrical load 146 discussed above) may be used to develop the wellbore 220 and/or to extract and/or transport a subterranean resource 211 from the wellbore 220 on production. The subsea electrical load 246 in this case is positioned on the seabed 202 in the water 294. The subsea electrical equipment 245 (substantially similar to the subsea electrical equipment 145 discussed above) is used to provide power to the subsea electrical load 246 using power transfer links 287 (e.g., electrical cables) and is also positioned on the seabed 202 in the water 294. The subsea electrical equipment 245 receives power and control signals from the power source 243 and junction box 244 on the topsides 207 of the floating structure 203 using power transfer links 287 and communication links 205, respectively, in the form of one or more electrical cables.

The system 200 includes a ROV 250 that moves within the water 294 to perform inspections and/or maintenance. The ROV 250 in this case is tethered to the topsides 207 of the floating structure 203 via a cable that may also serve as power transfer links 287 and/or communication links 205. The ROV 250 includes a controller 204-2 (e.g., substantially similar to the controllers 104 discussed above) and one or more sensor devices 260 (e.g., substantially similar to the sensor devices 160 discussed above). In some cases, the controller 204-2 and the sensor devices 260 are used to manipulate and move the ROV 250. In other cases, the controller 204-2 and the sensor devices 260 may additionally be used to measure power-related parameters associated with the subsea electrical equipment 245 and/or the subsea electrical load 246 using access provided by the ILCs 210, store the measurements, follow protocols, run models or other forms of algorithms using the measurements, communicate with the network manager (e.g., network manager 180) and/or a user system (e.g., user system 155) using communication links 205 (e.g., wirelessly, by coupling complementary connector ends), assess results of the models, and/or perform other functions.

The ROV 250 may be configured to mechanically couple to and, in some cases, communicate with (e.g., send instructions to, receive data from) one or more of the example ILCs 210 using an extension 258, which is configured to become coupled to (e.g., inserted into) a coupling feature 222 (e.g., in the form of an end of an electrical connector) of the ILC 210. In this case, there are two ILCs 210 (ILC 210-1 with coupling feature 222-1 and ILC 210-2 with coupling feature 222-2) in the water 294. ILC 210-1 is connected in parallel to the power transfer link 287 on the high side (between the subsea electrical equipment 245 and the junction box 244) of and proximate to the subsea electrical equipment 245. ILC 210-2 is connected in parallel to the power transfer link 287 on the low side (between the subsea electrical equipment 245 and the subsea electrical load 246) of and proximate to the subsea electrical equipment 245. In this case, the ILCs 210 are purely mechanical devices that include an end of an electrical connector that complements the end of an electrical connector disposed on the distal end of the extension 258 of the ROV 250.

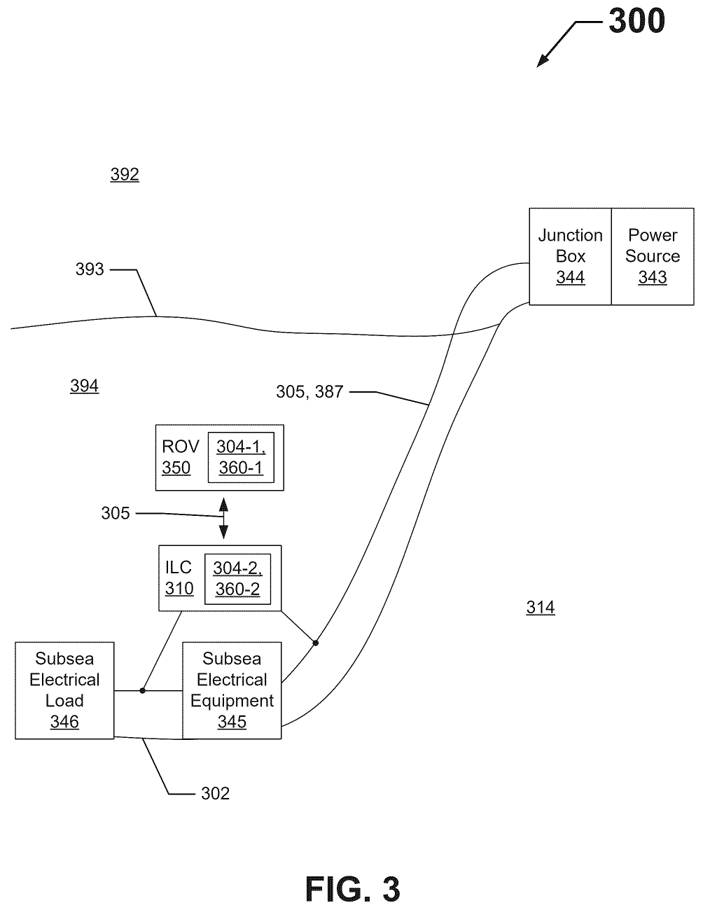

FIG. 3 shows another embodiment of a subsea electrical system 300 (also sometimes more simply called a system 300) according to certain example embodiments. Referring to the description above with respect to FIGS. 1 and 2, part of the system 300 of FIG. 3 in this case is on land (atop a subterranean formation 314 and in air 392 above the water level 393). Specifically, the power sources 343 (substantially similar to the power sources discussed above) and the junction boxes 344 (substantially similar to the junction boxes discussed above) are located on land near the water 394. The power sources 343 and the junction boxes 344 in this case are used to supply power used for subsea field operations (e.g., pipeline operations). There may be one or more of a number of other components (e.g., a controller, a sensor device) located on land working in conjunction with the power sources 343 and/or the junction boxes 344.

The subsea electrical load 346 (substantially similar to the subsea electrical loads discussed above) may be used to run equipment (e.g., pumps, compressors) used for performing the subsea field operation. The subsea electrical load 346 in this case is positioned on the seabed 302 in the water 394. The subsea electrical equipment 345 (substantially similar to the subsea electrical equipment discussed above) is used to provide power to the subsea electrical load 346 using power transfer links 387 (e.g., electrical cables) and is also positioned on the seabed 302 in the water 394. The subsea electrical equipment 345 receives power and control signals from the power source 343 via the junction box 344 on land using power transfer links 387 and communication links 305, respectively, in the form of one or more electrical cables.

The system 300 includes a ROV 350 that moves within the water 394 to perform inspections and/or maintenance. The ROV 350 in this case operates without a physical tether, as in FIG. 2. The ROV 350 may have communication capability to communicate with an entity (e.g., a user system (e.g., user system 155), a network manager (e.g., network manager 180)) on land using a wireless form of communication links 205. The ROV 250 includes a controller 304-1 (e.g., substantially similar to the controllers 104 discussed above) and one or more sensor devices 360-1 (e.g., substantially similar to the sensor devices 160 discussed above). In some cases, the controller 304-1 and the sensor devices 360-1 are used to manipulate and move the ROV 350. In other cases, the controller 304-1 and the sensor devices 360-1 may additionally be used to store measurements (e.g., made by one or more sensor devices 360-2 of the ILC 310, discussed below) of power-related parameters associated with the subsea electrical equipment 345 and/or the subsea electrical load 346 using access provided by the ILC 310, store the measurements, follow protocols, run models or other forms of algorithms using the measurements, communicate with the network manager (e.g., network manager 180) and/or a user system (e.g., user system 155) using communication links 305 (e.g., wirelessly, by coupling complementary connector ends), assess results of the models, and/or perform other functions.

The ROV 350 in this case may be configured to wirelessly communicate with (e.g., send instructions to, receive data from) the example ILC 310. Alternatively, the ROV 350 may include an extension (e.g., similar to the extension 258 discussed above), which may be configured to become coupled to (e.g., inserted into) a coupling feature (e.g., similar to the coupling features 222 discussed above) of the ILC 310. In this case, there is one ILC 310 in the water 394. In this case, the ILC 310 is connected in parallel to two locations. The first location that the ILC 310 is connected is in parallel with the power transfer link 387 on the high side (between the subsea electrical equipment 345 and the junction box 344) of and proximate to the subsea electrical equipment 345. The second location that the ILC 310 is connected is in parallel with the power transfer link 387 between the subsea electrical equipment 345 and the subsea electrical load 346. In this case, the ILC 310 includes one or more controllers 304-2 and one or more sensor devices 360-2, which allows the ILC 310 to have full measurement, analytical, and/or communication capabilities. The ILC 310 may or may not have a coupling feature (e.g., similar to the coupling features 222 discussed above) that complements the end of an electrical connector disposed on the distal end of an extension of the ROV 350.

FIG. 4 shows a schematic diagram of a subsea electrical system 400 according to certain example embodiments. Referring to the description above with respect to FIGS. 1 through 3, the subsea electrical system 400 of FIG. 4 shows a power source 443 (substantially similar to the power sources discussed above) that feeds high voltage (e.g., at least 1 kV) three-phase AC power to a junction box 444 (substantially similar to the junction boxes discussed above) using three power transfer links 487-1 (substantially similar to the power transfer links discussed above) in the form electrical cables. The power source 443 and the junction box 444 are in air 492 above the water line 493 and the water 494.

From the junction box 444, a power transfer link 487-2 (in the form of a power umbilical) is mostly placed in the water 494 to terminate at a piece of subsea electrical equipment 445-1 in the form of a SUTA. Each of the junction box 444 and the subsea electrical equipment 445-1 has three phases with one electrical cable or set of electrical cables for each phase. From the subsea electrical equipment 445-1, a power transfer link 487-3 (in the form of one or more electrical cables) is disposed in the water 494 to terminate at another piece of subsea electrical equipment 445-2 in the form of a step-down transformer. Each of the subsea electrical equipment 445-1 and the subsea electrical equipment 445-2 has three phases with one electrical cable or set of electrical cables for each phase.

Also, branching from the power transfer links 487-3 between the subsea electrical equipment 445-1 and the subsea electrical equipment 445-2 is an example ILC 410-1 (substantially similar to the ILCs discussed above and as described in more detail below with respect to FIGS. 6 through 8C. From the subsea electrical equipment 445-2, a power transfer link 487-4 (in the form of one or more electrical cables) is disposed in the water 494 to terminate at a subsea electrical load 446 in the form of a subsea motor and associated distribution system. Each of the subsea electrical equipment 445-2 and the subsea electrical load 446 has three phases with one electrical cable or set of electrical cables for each phase. Branching from the power transfer links 487-4 between the subsea electrical equipment 445-2 and the subsea electrical load 446 is another example ILC 410-2.

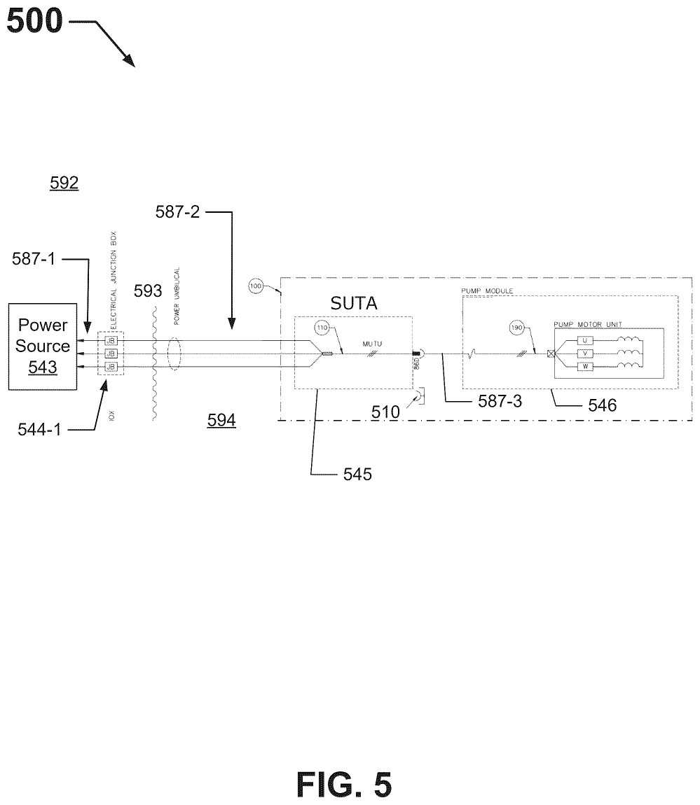

FIG. 5 shows a schematic diagram of another subsea electrical system 500 according to certain example embodiments. Referring to the description above with respect to FIGS. 1 through 4, the subsea electrical system 500 of FIG. 5 shows a power source 543 (substantially similar to the power sources discussed above) that feeds high voltage (e.g., at least 1 kV) three-phase AC power to a junction box 544 (substantially similar to the junction boxes discussed above) using three power transfer links 587-1 (substantially similar to the power transfer links discussed above) in the form electrical cables. The power source 543 and the junction box 544 are in air 592 above the water line 593 and the water 594.

From the junction box 544, a power transfer link 587-2 (in the form of a power umbilical) is mostly placed in the water 594 to terminate at a piece of subsea electrical equipment 545 in the form of a SUTA. In other words, in this case, the subsea electrical equipment 545 does not include a transformer or other type of power manipulation device. Each of the junction box 544 and the subsea electrical equipment 545 has three phases with one electrical cable or set of electrical cables for each phase. From the subsea electrical equipment 545-1, a power transfer link 587-3 (in the form of one or more electrical cables) is disposed in the water 594 to terminate at a subsea electrical load 546 in the form of a subsea pump module (including motor) and associated subsea electrical distribution system. Each of the subsea electrical equipment 545 and the subsea electrical load 546 has three phases with one electrical cable or set of electrical cables for each phase. Also, branching from the power transfer links 587-3 between the subsea electrical equipment 545 and the subsea electrical load 546 is an example ILC 510 (substantially similar to the ILCs discussed above and as described in more detail below with respect to FIGS. 6 through 8C.

FIG. 6 shows a general component diagram of an example ILC 610 according to certain example embodiments. Referring to the description above with respect to FIGS. 1 through 5, the ILC 610 in this case includes one or more jumpers 625, a base 611, multiple terminals 615, one or more optional controllers 604, one or more optional sensor devices 660, and one or more optional energy storage devices 620. All of these components of the ILC 610 may be configured to withstand the conditions (e.g., subsea, high pressure, low temperature, saline environment) that exist in the water (e.g., water 194) in which the ILC 610 may be used for extended periods of time (e.g., months, years, decades).

The base 611 of the ILC 610 is configured to secure each of the terminal 615 and house the optional controllers 604, sensor devices 660, and energy storage devices 620. The base 611 can be of any shape and/or size to accommodate the shape, size, spacing, and/or other characteristics required of the terminals 615 for the subsea electrical equipment (e.g., subsea electrical equipment 145) and/or the subsea electrical load (e.g., subsea electrical load 146) to be monitored and/or tested.

The ILC 610 can have any number (e.g., 2, 3, 4, 12) of terminals 615. In this case, the ILC 610 has X terminals 615 (terminal 615-1 through terminal 615-X). Each terminal 615 has an end (e.g., a distal end) that is configured to couple to an electrical cable that is coupled upstream or downstream of subsea electrical equipment (e.g., subsea electrical equipment 145). In some cases, each terminal 615 may have another end (e.g., a proximal end) that is configured as an end of an electrical connector (e.g., includes one or more coupling features (e.g., slots, tabs) that are configured to couple to a complementary coupling feature on an extension (e.g., extension 258) of a ROV (e.g., ROV 250) and/or some other device (e.g., a handheld meter when the ILC 610 is brought out of the subsea environment).

Each terminal 615 of the ILC 610 includes a body 614 and one or more jumper receivers 618. For example, in this case, terminal 615-1 has a body 614-1 and one or more jumper receivers 618-1, and terminal 615-X has a body 614-X and one or more jumper receivers 618-X. Some or all of the body 614 of a terminal 615 is made of an electrically conductive material. Some or all of a terminal 615 may be referred to as a cap herein. The body 614 of a terminal 615 may be a single piece or an assembly of pieces (e.g., brackets, bolts, rivets, adjoining cylinders). In some cases, some or all of a terminal 615 is filled with a fluid (e.g., oil) for successful operation in subsea conditions. In this way, the terminal 615 (and so the ILC 610) may be fully or partially insulated.

Each jumper receiver 618 is configured to receive and hold an end of a jumper 625. The ILC 610 can have any number (e.g., one, two, four, ten) of jumpers 625. In some alternative embodiments, two or more phases may be shorted without external jumpers (e.g., using a 3-phase contactor where the phases are shunted inside the ILC 610). In this way, the shunt serves as a jumper that is inaccessible and cannot be removed without disassembling the ILC 610. In this case, there are Y jumpers 625 (jumper 625-1 through jumper 625-Y). Each jumper 625 is made, at least in part, of an electrically conductive material. Each jumper 625 (also sometimes called a loop herein) is configured to electrically tie or “loop together” two of the terminals 615 of the ILC 610 to each other. In some cases, one or more jumpers 625 of the ILC 610 is set at the factory when the ILC 610 is made. In such cases, the position of each jumper 625 and the number of jumpers 625 of the ILC 610 may not be altered by a user (e.g., user 151).

In other cases, one or more of the jumpers 625 may be configured and/or selected in the field (e.g., before being placed in the water 194, in situ while in the water 194). In such cases, a jumper 625 and associated jumper receivers 618 may be configured substantially as shown in FIG. 6. Alternatively, one or more of the jumpers 625 of the ILC 610 may be configured differently while still meeting the functional requirement of electrically connecting two terminals 615. For example, the ILC 610 may include a rotary switch that allows a user 151 to configure one or more jumpers 625 relative to the terminals 615 by changing a position of the rotary switch relative to the base 611 of the ILC 610. Such a rotary switch (or other means of manipulating one or more jumpers 625 relative to the terminals 615) may operate mechanically (e.g., a manual turning) or electrically (e.g., follow a digital instruction). In some cases, a jumper 625 may only be positioned when the ILC 610 is not in the water 194. Alternatively, the position of a jumper 625 may be changed when the ILC 610 is in situ in the water 194.

The position of the one or more jumpers 625 may be driven by the type of testing and/or measurements to be taken relative to the subsea electrical equipment 145 and/or the subsea electrical load 146. For example, two terminals 615 (e.g., two phases) may be short circuited (shunted without any inline resistor (e.g., using an electrical wire, using a busbar connector)) and operated up to a rated current. As another example, all terminals 615 (e.g., all phases) may be short circuited (shunted without any inline resistor (e.g., using an electrical wire, using a busbar connector)). As yet another example, the ILC 610 may replace a FIDC in the field (where the ILC phases can be isolated in addition to the functionality stated previously), where the ILC 610 may operate at the rated voltage of the subsea electrical equipment.

By using the jumpers 625, the ILC 610 may be used to perform any of a number of tests and monitoring techniques that existing FIDCs are not capable of performing or have only limited capability of performing, including but not limited to, continuity line resistance testing (DC or AC), bridge method testing, AC loop impedance metering, vector impedance metering, line resonance analysis (LIRA), and induced current method (ICM). In addition, since the example ILC 610 is able to withstand exposure to higher voltage levels (e.g., 138 kV, 245 kV) without failing, the ILC 610 may be used in testing and monitoring up to or exceeding the rated voltage level of the subsea electrical equipment 145 and/or the subsea electrical load 146.

The inclusion of the controller 604, the sensor devices 660, and the energy storage devices 620 allow the example ILC 610 to be a smart device. Each controller 604 and each sensor device 660 may be substantially the same as the controllers and the sensor devices discussed above. For example, a controller 604 may include components such as a control engine, an evaluation module, a compensation module, a calibration module, a communication module, a timer, a power module, a storage repository (e.g., for storing protocols, for storing algorithms (e.g., models), for storing stored data), a hardware processor, a memory, a transceiver, an application interface, and a security module.

When one or more ILCs 610 are connected to subsea electrical equipment 145 and/or subsea electrical load 146, each ILC 610 may determine or facilitate the determination of information about the subsea electrical equipment 145 and/or subsea electrical load 146. Such information may be used before the subsea electrical equipment 145 and/or subsea electrical load 146 is put in service (e.g., fingerprinting), during steady state operation of the subsea electrical equipment 145 and/or subsea electrical load 146 (e.g., trending relative to a fingerprinted profile), during a problem (e.g., a short, a fault, the start or progression of a problem that will eventually result in a short or a fault) to identify the problem and its particulars (e.g., the precise location of a fault or short or emerging problem, the estimated amount of time before an emerging problem becomes a fault, short, or other irreversible problem).

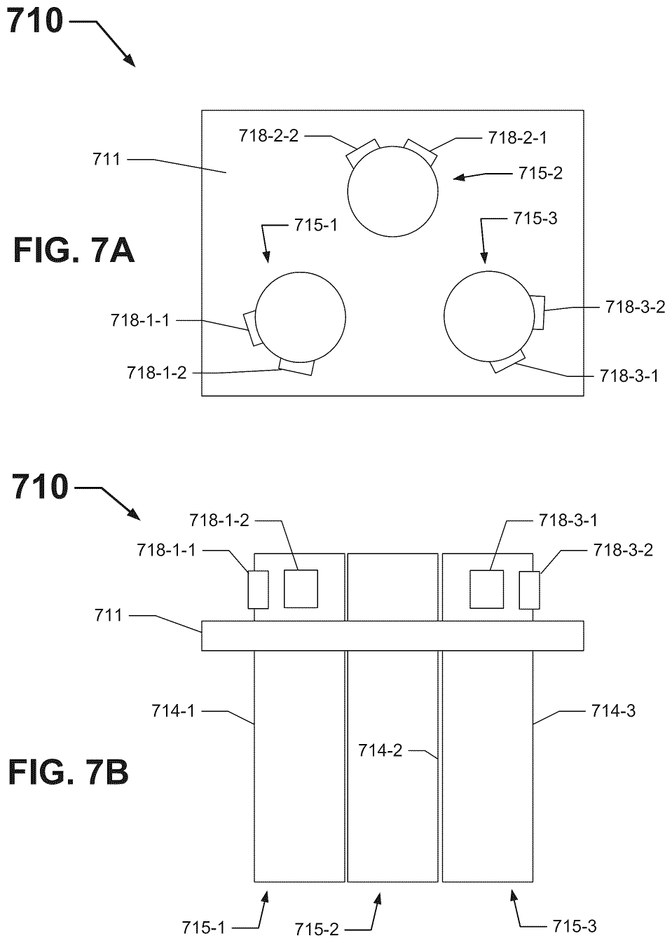

FIGS. 7A and 7B show a top view and a front view, respectively, of an ILC 710 according to certain example embodiments. Referring to the description above with respect to FIGS. 1 through 6, the ILC 710 in this case is substantially the same as the ILC 610 discussed above with respect to FIG. 6, except as discussed below. For example, the ILC 710 of FIGS. 7A and 7B has a base 711 and three terminals 715 (terminal 715-1, terminal 715-2, and terminal 715-3). Each terminal 715 has a body 714 and two jumper receivers 718. Specifically, terminal 715-1 has a body 714-1 and two jumper receivers 718-1 (jumper receiver 718-1-1 and jumper receiver 718-1-2). Terminal 715-2 has a body 714-2 and two jumper receivers 718-2 (jumper receiver 718-2-1 and jumper receiver 718-2-2). Terminal 715-3 has a body 714-3 and two jumper receivers 718-3 (jumper receiver 718-3-1 and jumper receiver 718-3-2). The jumpers (similar to the jumpers 625 above) are not shown in FIGS. 7A and 7B.

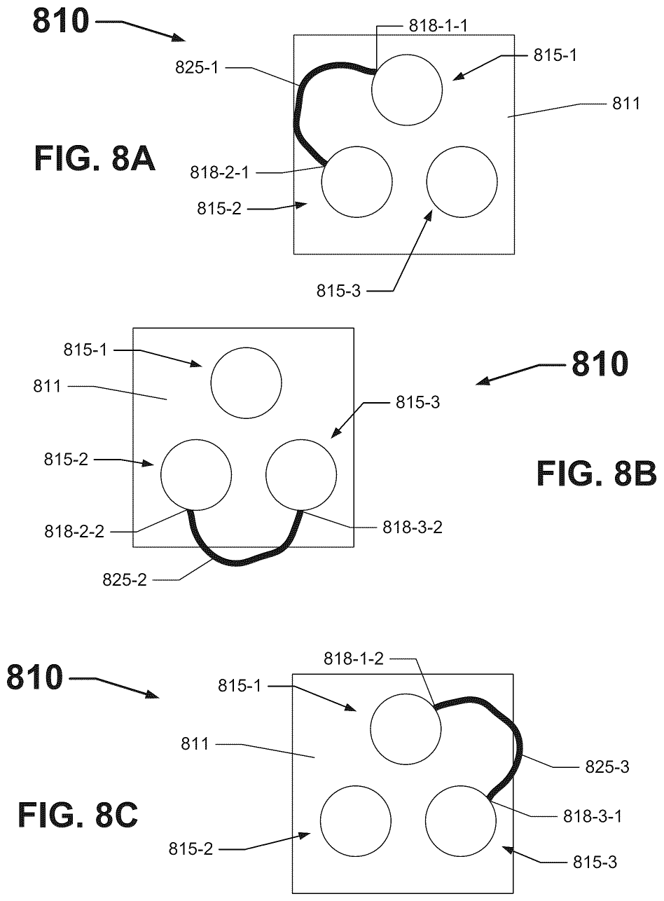

FIGS. 8A through 8C show various configurations of a jumper for an ILC 810 according to certain example embodiments. Referring to the description above with respect to FIGS. 1 through 7B, the ILC 810 shown in FIGS. 8A through 8C include a base 811, a single jumper 825, and three terminals 815 (terminal 815-1, terminal 815-2, and terminal 815-3). In FIG. 8A, the ILC is configured so that a jumper 825-1 is connected to a jumper receiver 818-1-1 of terminal 815-1 and to a jumper receiver 818-2-1 of terminal 815-2. In FIG. 8A, the ILC 810 is configured so that a jumper 825-1 is connected to a jumper receiver 818-1-1 of terminal 815-1 and to a jumper receiver 818-2-1 of terminal 815-2. In FIG. 8B, the ILC 810 is configured so that a jumper 825-2 is connected to a jumper receiver 818-2-2 of terminal 815-2 and to a jumper receiver 818-3-2 of terminal 815-3. In FIG. 8C, the ILC 810 is configured so that a jumper 825-3 is connected to a jumper receiver 818-1-2 of terminal 815-1 and to a jumper receiver 818-3-1 of terminal 815-3.

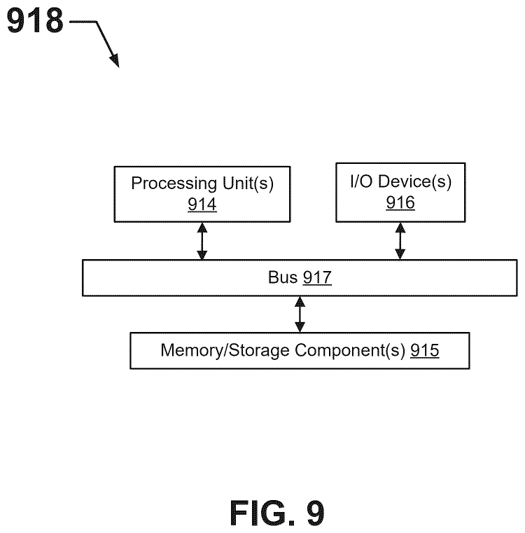

FIG. 9 illustrates one embodiment of a computing device 918 that implements one or more of the various techniques described herein, and which is representative, in whole or in part, of the elements described herein pursuant to certain example embodiments. For example, a controller (e.g., a controller 104) (including components thereof, such as a control engine, a hardware processor, a storage repository, a power module, and a transceiver) of a ILC 110, a ROV 150, a user system 155, etc. may be considered a computing device 918. Computing device 918 is one example of a computing device and is not intended to suggest any limitation as to scope of use or functionality of the computing device and/or its possible architectures. Neither should the computing device 918 be interpreted as having any dependency or requirement relating to any one or combination of components illustrated in the example computing device 918.

The computing device 918 includes one or more processors or processing units 914, one or more memory/storage components 915, one or more input/output (I/O) devices 916, and a bus 917 that allows the various components and devices to communicate with one another. The bus 917 represents one or more of any of several types of bus structures, including a memory bus or memory controller, a peripheral bus, an accelerated graphics port, and a processor or local bus using any of a variety of bus architectures. The bus 917 includes wired and/or wireless buses.

The memory/storage component 915 represents one or more computer storage media. The memory/storage component 915 includes volatile media (such as random access memory (RAM)) and/or nonvolatile media (such as read only memory (ROM), flash memory, optical disks, magnetic disks, and so forth). The memory/storage component 915 includes fixed media (e.g., RAM, ROM, a fixed hard drive, etc.) as well as removable media (e.g., a Flash memory drive, a removable hard drive, an optical disk, and so forth).

One or more I/O devices 916 allow a user 151 to enter commands and information to the computing device 918, and also allow information to be presented to the user 151 and/or other components or devices. Examples of input devices 916 include, but are not limited to, a keyboard, a cursor control device (e.g., a mouse), a microphone, a touchscreen, and a scanner. Examples of output devices include, but are not limited to, a display device (e.g., a monitor or projector), speakers, outputs to a lighting network (e.g., DMX card), a printer, and a network card.

Various techniques are described herein in the general context of software or program modules. Generally, software includes routines, programs, objects, components, data structures, and so forth that perform particular tasks or implement particular abstract data types. Implementations of these modules and techniques are stored on or transmitted across some form of computer readable media. Computer readable media is any available non-transitory medium or non-transitory media that is accessible by a computing device. By way of example, and not limitation, computer readable media includes “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which is used to store the desired information and which is accessible by a computer.

The computer device 918 (also sometimes called a computer system 918 herein) is connected to a network (not shown) (e.g., a LAN, a WAN such as the Internet, cloud, or any other similar type of network) via a network interface connection (not shown) according to some example embodiments. Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means take other forms, now known or later developed, in other example embodiments. Generally speaking, the computer system 918 includes at least the minimal processing, input, and/or output means necessary to practice one or more embodiments.

Further, those skilled in the art will appreciate that one or more elements of the aforementioned computer device 918 is located at a remote location and connected to the other elements over a network in certain example embodiments. Further, one or more embodiments are implemented on a distributed system having one or more nodes, where each portion of the implementation (e.g., a ILC 110, a ROV 150, a user system 155) is located on a different node within the distributed system. In one or more embodiments, the node corresponds to a computer system. Alternatively, the node corresponds to a processor with associated physical memory in some example embodiments. The node alternatively corresponds to a processor with shared memory and/or resources in some example embodiments.

Example embodiments may be used to allow for expanded fingerprinting, problem detection, and/or problem location identification associated with subsea electrical equipment and/or subsea electrical loads. In some cases, example embodiments are purely mechanical connectors that allow a ROV or other entity to measure parameters associated with performance of the subsea electrical equipment, the subsea electrical loads, and/or the electrical cables therebetween. In other cases, example embodiments may additionally include one or more sensor devices to measure parameters such as, for example, voltage, current, VARs, and resistance. In yet other cases, example embodiments may additionally include one or more controllers to store the measurements, format the measurements, organize the measurements, run algorithms using the measurements, interpret the results of the algorithms, make a detailed identification of a problem with the subsea electrical equipment, the subsea electrical loads, and/or the electrical cables therebetween, make recommendations, and/or perform any other suitable function. In such cases, example embodiments may continually, or in discrete time increments, take measurements and/or transmit the data associated with those measurements. The example ILC may be connected in parallel with electrical cables in a subsea environment without affecting the operation of the subsea electrical equipment and/or the subsea electrical load. Example embodiments result in increased reliability of subsea electrical equipment and/or the subsea electrical loads. Example embodiments may be used with new subsea electrical equipment and/or the subsea electrical loads or retrofit to work with existing subsea electrical equipment and/or the subsea electrical loads. Example embodiments may provide a number of benefits. Such benefits may include, but are not limited to, ease of use, short commissioning time, extending the life of subsea electrical equipment and/or the subsea electrical loads, flexibility, configurability, and improved compliance with applicable industry standards and regulations.

Although embodiments described herein are made with reference to example embodiments, it should be appreciated by those skilled in the art that various modifications are well within the scope of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A loop cap comprising:
a base having an outer surface and an inner surface, wherein the outer surface is configured to be exposed to a subsea environment;
a first terminal that extends through the base, wherein the first terminal has a first proximal portion that is configured to be electrically coupled to a first electrical conductor providing high voltage power to a subsea electrical system;
a second terminal that extends through the base, wherein the second terminal has a second proximal portion that is configured to be electrically coupled to a second electrical conductor providing high voltage power to the subsea electrical system; and
a jumper that provides electrical continuity between the first terminal and the second terminal.

2. The loop cap of claim 1, wherein the first terminal further has a first distal portion that is configured to be exposed to the subsea environment and to be electrically coupled to a test probe used to measure a power parameter associated with the subsea electrical system.

3. The loop cap of claim 2, wherein the second terminal further has a second distal portion that is configured to be exposed to the subsea environment and to be electrically coupled to a second test probe used to measure the power parameter associated with the subsea electrical system.

4. The loop cap of claim 2, wherein the test probe is controlled by a remotely operated vehicle.

5. The loop cap of claim 1, wherein a phase selection of the jumper is configurable between the first terminal, the second terminal, and a third terminal.

6. The loop cap of claim 5, wherein the phase selection between terminals is configurable subsea using a rotary switch.

7. The loop cap of claim 6, wherein the rotary switch operates mechanically.

8. The loop cap of claim 6, wherein the rotary switch operates electrically or electronically.

9. The loop cap of claim 5, wherein the phases are configurable topsides before the insulated loop cap is installed subsea.

10. The loop cap of claim 1, wherein the phase selection is in a fixed position and not configurable.

11. The loop cap of claim 1, wherein the jumper is internal to an enclosure of the loop cap and is inaccessible.

12. The loop cap of claim 1, further comprising:
a sensor device configured to measure a parameter associated with the subsea electrical system;
a controller communicably coupled to the sensor device, wherein the controller is configured to:
obtain a measurement made by the sensor device;
generate, using the measurement, an evaluation of the subsea electrical system; and
communicate the evaluation; and
an energy storage device configured to provide power to the controller and the sensor device.
